(19) United States
(12) Patent Application Publication
(10) Pub. No.: US 2026/0255730 A1
(43) Pub. Date: Aug. 27, 2026

(54) OPTOELECTRONIC DEVICE AND METHOD FOR PROCESSING THE SAME

(71) Applicant: ams-OSRAM International GmbH, Regensburg (DE)

(72) Inventors: Anna Kasprzak-Zablocka, Donaustauf (DE); Martin Hetzl, Painten (DE); Norwin von Malm, Thumhausen/Nittendorf (DE); Michael Binder, Barbing (DE)

(21) Appl. No.: 19/162,674

(22) PCT Filed: Mar. 8, 2024
(86) PCT No.: PCT/EP2024/056288

§ 371 Date: Sep. 5, 2025

(30) Foreign Application Priority Data
Mar. 9, 2023 (DE) 102023105932.7

(51) Int. Cl. H10H 20/00; H10H 20/01; H10H 20/816; H10H 20/831; H10H 20/84

(52) U.S. Cl. CPC H10H 20/062; H10H 20/032; H10H 20/034; H10H 20/816; H10H 20/831; H10H 20/84

(57) ABSTRACT

In an embodiment an optoelectronic device includes a semiconductor layer stack having a planar first semiconductor layer of a first doping type, an active layer and a second semiconductor layer of a second doping type, wherein the second semiconductor layer has a main emission surface layer portion, a contact layer arranged on the first semiconductor layer opposite at least a first portion of the active layer, and a structured contact layer arranged on the second semiconductor layer opposite a second portion of the active layer, wherein the first portion and the second portion are spatially offset in a lateral direction to each other and configured to increase a local charge carrier density in an active region of the active layer partially common to or adjacent to the first and second portions of the active layer, and wherein the active region is defined by a projection of an overlapping section of the first and second portions onto the active layer.

### CROSS-REFERENCE TO RELATED APPLICATIONS

This patent application is a national phase filing under section 371 of PCT/EP2024/056288, filed Mar. 8, 2024, which claims the priority of German patent application no. 10 2023 105 932.7, filed Mar. 9, 2023, each of which is incorporated herein by reference in its entirety.

### TECHNICAL FIELD

The present invention concerns an optoelectronic device as well as a method for processing an optoelectronic device.

### BACKGROUND

Optoelectronic devices also referred as μ-LEDs have become increasingly reduced in size and comprise a lateral dimension of a few micrometres, for example, in the range of 2 μm to 20 μm. The small size enables μ-LEDs to be used for optical data communication between hardware components in computer systems and networks, in optical networks and the like. The use of μ-LEDs for optical data communication provides some major benefits. Apart from the size, optoelectronic devices as VCSEL can be used due to an improved scalability and lower current consumption.

Normal μ-LEDs provide similar benefit and in addition comprise a lower energy consumption in short and medium range interconnects for data communication. The latter is relevant as the reduced power consumption also reduces the requirements towards heat removal or temperature constraints often found in highly dense packed hardware. However, besides a high quantum efficiency, these μ-LEDs and optoelectronic devices in general require a very fast switchability or capability of high modulation for the light emitting components in order to allow higher data rates. Such data rate range up to modulation rate of 10 GHz corresponds to pulses of approximately 0.1 ns. This pulses require to have rise and fall times of about 20 ps to be detectable without too high of an error rate.

The main limitation in this regard is the radiative recombination lifetime of the charge carriers, limiting the rise and fall times of light emissions in the μ-LEDs when modulating the current through the optoelectronic component. In PWM applications, in which the current is turned off and on, rise and fall times mainly given by the radiative recombination lifetime of the charge carriers are distorting the signal, thus requiring longer ON pulses. This reduces the achievable data rate.

The current solutions and μ-LEDs available have been proven to comprise a radiative recombination lifetime too long for the required rise and fall times to achieve data rates in the range of a few hundred megahertz and up to 1 GHz and are thus not optimal for such high data rates.

### SUMMARY

Embodiments provide an improved modulation frequency and switchability of μ-LEDs and optoelectronic components in general to allow for high data rates in the range of a few hundred MHz to a few Ghz.

Embodiments of the present application propose design changes to the semiconductor structure of an optoelectronic component like μLEDs and lasers as for examples VCSELs in order to increase the local charge carrier density in an active region of the optoelectronic device. The increased local charge carrier density reduces the radiative lifetime when modulating the current through the device. In this regard, the modulation can be only partial-that is between two different operating current (corresponding to a modulation depth of less than 100%)—, but also digital as in a PWM modulation.

The design changes of the optoelectronic device may reduce the quantum efficiency and light intensity during operation of the component. However, by improving the light extraction efficiency using various techniques, the switchability of the optoelectronic device is significantly increased without compromising too much extraction efficiency.

The approaches of decreasing the radiative lifetime currently known include a background doping in the barrier or directly in the quantum well in order to increase the charge carrier density. However, such approach, although beneficial is limited to the small current regime and may only work for certain a dedicated currents. As an alternative, the material quality can be reduced by implementing non-radiative defect centres to decrease the charge carrier lifetime. However, this has usually a negative impact on the internal quantum efficiency and the long-term stability of the device.

In the proposed principle, the electrical contacts for the n-doped and p-doped semiconductor material are laterally and spatially offset towards each other. The offset leads to an enhancement of the local current density or charge carrier density in operation of the device within a portion of the active layer referred to as active region. The increase of the local charge carrier density will significantly improve the switching and modulation speed. By additional measures like for example, removing certain portions of the top contact layer, the absorption therein is reduced, and the light extraction increased. Further measures like roughening or etching the light emission surface also facilitates and improve light extraction.

In some further aspects, the semiconductor layer stack of the optoelectronic device may be etched selectively to provide a high surface to volume ratio. This allows for fast carrier relaxation, thereby improving the overall modulation speed.

In an aspect of the proposed principle an optoelectronic device comprises a semiconductor layer stack having a planar first semiconductor layer of a first doping type, a second semiconductor layer of the second doping type and an active layer arranged in between. The second semiconductor layer may also comprise a main emission surface layer portion. In other words, light being generated in the active layer during operation of the optoelectronic device is emitted through the main emission surface layer portion. The optoelectronic device further comprises a contact layer arranged on the first semiconductor layer opposite at least a first portion of the active layer. Furthermore, a structured contact layer is provided arranged on the second semiconductor layer opposite the second portion of the active layer.

In accordance with the proposed principle, the first portion and second portion are laterally spatially offset towards each other. Such configuration increases the local charge carrier density in an active region of the active layer defined by the offset which can be partially common to or adjacent to the first and second portion of the active layer, respectively.

By providing a structured contact layer and locating the contact layer, such that a spatial lateral offset is generated, a reduction of the effective active layer is achieved by reducing the current spreading through the semiconductor layers. The reduced, effective active layer is referred to as active region for the purpose of the present application.

Consequently, in some aspects of the proposed principle, the active region is defined by a projection of the overlapping section of the first and second portions of the active layer, i.e. the portion of the active layer covered by the overlapping section. The charge carrier density in operation of the device is largest in such overlapping sections. As an alternative, the active region can be represented by a projection of the edges of the contact layer and the structured contact layer facing each other onto the active layer, i.e. the area of the active region within a projection of the edges towards the active layer. In such embodiment, the contact layer and the structured contact layer do not overlap each other, but are spatially set apart in a lateral direction. However, the area in between the edges of the respective contact layer and structured contact layer facing each other comprise an increased charge carrier density in operation of the device and thereby constitutes the active region.

By properly structuring the respective contact layers, one can form an active region in certain shapes. For example, an active region can be implemented as a closed circumferential structure, in particular a ring or polygon-shaped structure surrounding one of the first and second portions and being surrounded by the respective other one of the first and second portions, respectively. When viewed from a top or bottom, the active region thereby forms a polygon or a ring in operation of the device.

It is useful in some aspects to provide the active layer with a larger area than an area of the contact layer in order to form an active region comprising well defined current constraints or charge carrier constraints within. In some further aspects, the structured contact layer may form a closed circumferential structure, in particular a ring or a polygon when viewed from top. The circumferential structure surrounds the main emission surface layer portion in some aspects.

Some aspects relate to further design changes compared to conventional optoelectronic devices. In some aspects, the second semiconductor layer is at least partially recessed in the area of the main emission surface layer portion. In other words, some material of the second semiconductor layer is removed in the area of the main emission surface layer portion. In some aspects, the second semiconductor layer comprises a plurality of layers with one of those sublayers being a highly n-doped current spreading distribution layer.

This sublayer may be arranged partially opposite the second portion of the active layer. Hence, in some aspects, the highly doped current spreading distribution sublayer opposite first portion of the active layer is at least partially recessed, such that its thickness is reduced. This will prevent an undesired current spreading of charge carriers being injected through the structured contact layer. In some aspects, the recess can extend not only through portions of the second semiconductor layer but also through the active layer itself. In such aspects, the active layer may form a closed circumferential structure, in particular a ring or a polygon with its central portion being removed.

In some aspects, the recess can be filled up with an insulating material different from the material of the active layer. In some aspects, the exposed sidewalls of the second semiconductor layer as well as the active layer can be covered by a thin layer of a dielectric material, for example SiO2 or Al2O3.

In some further aspects, a dielectric material is covering the sidewalls of the contact layer, the first semiconductor layer and the active region, respectively. That dielectric material may be deposited on the outer sidewalls of such layers. This is for example the case, in which the optoelectronic device is a mesa structured component. In some further aspects, the dielectric material may be in turn covered by a reflective layer like for instance a reflective metal and the like. Said material can be part of the metal contact contacting the contact layer deposited on portions of the dielectric material. The reflective metal on the sidewalls acts as a mirror for reflecting generated light back towards the main emission surface.

Some further aspects concern an increased switching speed by providing secondary electrodes to inject into or deplete additional charge carriers from the active region during modulation or switching the optoelectronic device. Consequently in accordance with the proposed principle, the optoelectronic device further comprises a first secondary electrode, which electrically connects one of the first semiconductor layer and the second semiconductor layer at a location outside the respective one of the first and second portions. As a result, one of the first and second semiconductor layers now comprises two possibilities for carrier injection or carrier depletion; one being the main contact layer or structured contact layer, respectively, and the other one the proposed additional first secondary electrode.

In some aspects, the optoelectronic device is further improved by a second secondary electrode, which connects the other one of the first semiconductor layer and the second semiconductor layer at the location outside the respective one of the first and second portion. As a result, carrier injection or depletion can be enhanced by additionally applying a current to the first and second secondary electrode, respectively. Such structure will therefore allow to modulate an optoelectronic device by a respective current through the additional secondary electrodes while maintaining a biased operation with a main current through the contact layer and the structured contact layer, respectively.

In some aspects, the first and/or second secondary electrode may form a ring shape structure surrounding the respective one of the first and second portions.

In the above-mentioned aspects, an additional current is injected into the active region by the first and second secondary electrodes. However, a similar approach can be realized by design integration of a gate potential such that the operation of the optoelectronic component is possible without an additional integrated circuit for switching the component.

In some aspects, the μ-LEDs and optoelectronic device comprises a dielectric gate material, which is deposited on the sidewall portion of the active layer, extending partially onto an adjacent sidewall portion of at least one of the first and second semiconductor layers. A metal contact forming a conductive contact gate is applied on the dielectric material.

As a result, a transistor gate is formed adjacent to the active layer (or active region) providing the possibility to steer the optoelectronic device via a third potential. The gate can cover solely the active layer alone or the active layer together with one of the first and second semiconductor layers. In some further aspects, a gate can also be applied to one of the doped layers close to the active region. This would allow to constrict the transport and diffusion of charge carriers through such section. Furthermore, even a combination of all the before mentioned regions and layers is possible. This can realize with the gate being a classical 2D sheet gate as well as more complex structure like a circumferential gate around the sidewall of the active region.

Consequently, in some aspects, the dielectric material is arranged substantially parallel to a diffusion direction of the charge carrier in operation of the device. Alternatively, or in addition, the dielectric material may also be arranged substantially perpendicular to the active region. In cases, in which the optoelectronic device comprises a centrally arranged recess through the active layer, the gate material can be provided on the inner sidewalls of such recess directly adjacent to the active region. In addition, a second gate material can be deposited on the outer circumferential the sidewalls of the active layer.

Another aspect concerns a method of processing an optoelectronic device. The method requires providing a mesa etched layer stack having a first semiconductor layer of a first doping type, a second semiconductor layer of a second doping type and an active layer in between. A contact layer is deposited on the first semiconductor layer opposite at least a first portion of the active layer. The layer stack may then be re-bonded and a temporary growth substrate is removed to expose the second semiconductor layer's surface.

A structured contact layer is subsequently arranged on the second semiconductor layer opposite a second portion of the active layer, such that at least a portion of the second semiconductor layer's surface opposite the contact layer is exposed. The respective steps of depositing of the contact layer and the structured contact layer are conducted such that the respective layers comprise a spatial offset towards each other in a lateral direction. This will increase a local charge carrier density in an active region of the active layer between the respective first and second portions of the active layer.

As mentioned above, the active region is defined in the active layer by a projection of an overlapping section or a projection of the edges of the respective contact layers facing each other. Depending on the respective implementation, the active region can form a closed circumferential structure, like a ring or a polygon.

In some further aspects, the method according to the proposed principle comprises recessing the second semiconductor layer surface opposite the contact layer to form a recess. Hence, a portion of the second semiconductor layer material is removed. The removed portion may constitute a part of a highly doped current distribution layer being part of the second semiconductor layer. Further, a portion of the active layer can also be removed. In some aspects of the proposed principle, a portion of the first semiconductor layer opposite the contact layer may be removed to expose either the surface of the contact layer or some remaining material of the first semiconductor layer.

In some further aspects, the step of providing a mesa etched layer comprises the step of depositing a dielectric material on the sidewalls of the first semiconductor layer and the active layer, respectively. Optionally, such dielectric material may also be deposited on the second semiconductor layer. The deposition of the dielectric material depends on the depth of the mesa etch process. Optionally, in some aspects, a metal material can be deposited on the dielectric material acting as a reflective mirror for light being generated in the active region of the optoelectronic device.

In some further aspects, a first and secondary electrode may be deposited electrically connecting one of the first semiconductor layer and the second semiconductor layer at a location outside the respective one of the first and second portions. Both secondary electrodes can be implemented as a ring shaped structure surrounding the respective one of the first and second portions.

Likewise in an aspect, the method according to the proposed principle further comprises depositing a dielectric gate material on the sidewall portion of the active layer, extending partially onto an adjacent sidewall portion of at least one of the first and second semiconductor layer. As an alternative, the dielectric gate material may also cover only one or both doped layers close to the active region, thereby constricting the transport and diffusion of charge carriers through such section.

A metal contact is then deposited forming a conductive contact gate on the dielectric gate material. In this regard, the dielectric gate material may be arranged circumferential onto an inner sidewall of the active region. This is the case, when a recess as mentioned above is formed in the optoelectronic device and through the second semiconductor layer material. Likewise, the dielectric gate material may also be arranged on the circumferential outer sidewall of the active layer.

The first and semiconductor layers are of different doping type, whereas one skilled in the art may recognize that such doping type is not limited to a specific p- or n-doping for the respective first and second semiconductor layers. The doping of the semiconductor layers can be exchanged. In addition, the respective first and second semiconductor layer may comprise a plurality of layer with different doping concentrations, as well as distributions and spatial variations and the like. Furthermore, both semiconductor layers may comprise a undoped cladding layer directly adjacent to the active layer to prevent dopant diffusion into the active layer.

The active layer, in itself may comprise one or more quantum well structures multi-quantum well structure or a simple pn-junction. With regards to possible semiconductor materials, one should mention all kinds of III-V semiconductor material systems including Nitride, Arsenide and Phosphide systems. Examples therefore include GaN, GaP, GaAs, AlGaN, AlGaP, AlGaAs, InGaN, InGaP, InGaAs, InAlGaN, InGaAlP and InGaAlAs as well as combination thereof including different or varying concentration of In or Al content.

### BRIEF DESCRIPTION OF THE DRAWINGS

Further aspects and embodiments in accordance with the proposed principle will become apparent in relation to the various embodiments and examples described in detail in connection with the accompanying drawings in which

FIG. 1 shows a first embodiment of an optoelectronic device according to some aspects of the proposed principle;

FIG. 2 illustrates the top view of the optoelectronic device according to FIG. 1;

FIG. 3 shows a second embodiment of an optoelectronic device in accordance with some aspects of the proposed principle;

FIG. 4 illustrates a third embodiment of an optoelectronic device in accordance with some aspects of the proposed principle;

FIG. 5 shows a fourth embodiment of an optoelectronic device in accordance with some aspects of the proposed principle;

FIG. 6 illustrates a fifth embodiment of an optoelectronic device in accordance with some aspects of the proposed principle;

FIG. 7 shows a sixth embodiment of an optoelectronic device according to some further aspects of the proposed principle;

FIG. 8 illustrates the top view of the optoelectronic device according to FIG. 7;

FIG. 9 shows a seventh embodiment of an optoelectronic device according to some further aspects of the proposed principle;

FIG. 10 shows an eighth embodiment of an optoelectronic device according to some further aspects of the proposed principle; and

FIGS. 11A to 11E illustrate several process steps of processing an optoelectronic device in accordance with some aspects of the proposed principle.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or shape. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

In conventional embodiments of optoelectronic devices and μ-LEDs implemented as vertical devices, the respective metallic contact layer for the n-doped or for the p-doped side usually extend across the whole emission surface or across the whole active layer to guarantee a uniform current distribution into the active layer. Consequently, the respective semiconductor layers may also comprise highly doped current distribution sublayers to ensure a substantial equally distributed carrier injection into the active layer.

Embodiments of the present invention now propose to constrain the carrier injection only into a small section of the overall active layer, referred to as active region. In other words, injection of charge carriers into the semiconductor material and subsequently into the active layer, —at least from one side—, is no longer equally distributed across the whole area, but rather constraint into a small section of the available semiconductor material. As a result, the charge carrier density and the current density within that section significantly increases allowing very quick and fast carrier depletion or injection when modulating the current through the device or switching the optoelectronic device from an “ON” operating states to an “OFF” operating state and vice versa.

Hence, modulating the light emission by current amplitude modulation can occur significantly faster compared to conventional techniques, in which the available charge carriers are distributed across a larger area and thus require longer to recombine within the active area. The reduction of charge carrier lifetime limiting the radiative decay is achieved by constraining the charge carrier to a smaller portion of the active layer. Although the increased current density in only a small region of the active layer may result in an increased heat generation within that region, heat transport mechanisms are well established to ensure no damages is done to the optoelectronic device. The other potential disadvantage is a reduced light emission due to the smaller region, in which charge carrier can recombine. This disadvantage is however overcome by the increased switching and modulation speed of the device, particularly relevant for optical data communication.

The following embodiments are therefore optimized for a reduced radiative recombination lifetime, thereby improving the rise and fall time of light pulses when modulating the current through the optoelectronic device. In this regard, the present embodiments illustrated herein are subject to scale and therefore can be implemented in various sizes and various techniques. Although only μLEDs are shown herein, the proposed principle is transferable to VCSEL or other types of optoelectronic devices. In particular, the proposed principles are suitable for μ-LEDs having a size or dimensions smaller than 100 μm and down to approximately a few 10 μm or even less.

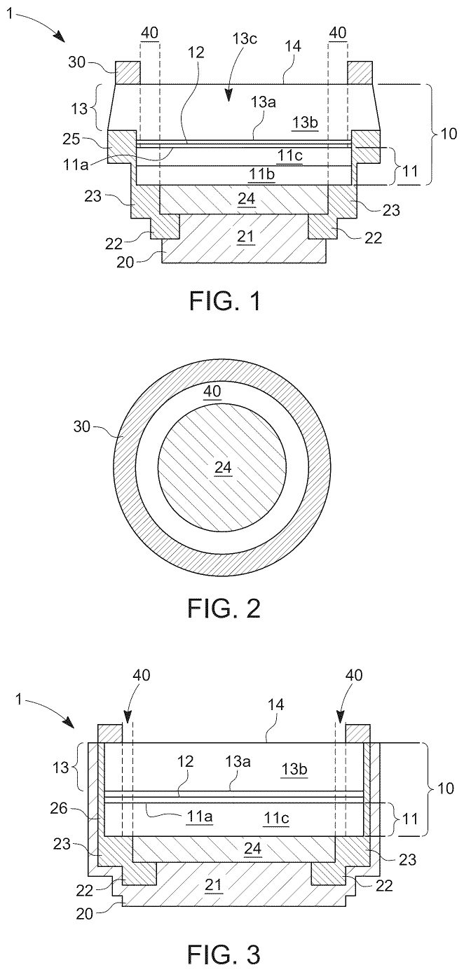

FIG. 1 illustrates a first embodiment according to the proposed principle.

The optoelectronic device or μ-LED 1 comprises a semiconductor layer stack 10. The semiconductor layer stack 10 includes a first semiconductor layer 11 of a first conductivity or doping type, an active region 12 as well as a second semiconductor layer 13 of a second doping type arranged on top of each other. The active layer 12 may comprise a single quantum well, a pn-junction or a multi-quantum well, respectively.

The respective semiconductor layers 11 and 13 further include one or more sublayers for current distribution and other functionalities, as it will be explained further below in greater detail. In this regard, the semiconductor layers 11 and 13 as well as the active layer 12 may comprise a III-V semiconductor material, and more particularly a ternary or quaternary material based on nitride, arsenide or phosphide material systems.

In particular semiconductor layer 11 comprises a current distribution sublayer 11b, a current transport layer 11c as well as an undoped cladding layer 11a directly adjacent to active layer 12. Likewise, the second semiconductor layer 13 comprises an undoped cladding layer 13a adjacent to the active layer, a current transport layer 13b as well as a current distribution layer 13c. Both cladding layers 13a and 11a are undoped to prevent an undesired diffusion of dopants of current transport layers 13b, and 11c, respectively into the active region. The current transport layer 11c and 13b comprise a doping concentration, which is constant, but may also vary with regard to the distance to the active region. Current distribution layers 11b and 13c are highly doped to provide an equal current distribution across the semiconductor layers 13 and 11, respectively.

The optoelectronic device 1 further comprises a first contact layer 24, which is arranged directly on the current distribution layer 11b of layer stack 10. Contact layer 24 may comprise a semiconductor material or metal and is connected to metal contact 20 within a recess 21 of insulating material 22. The metal contact 20 injects the charge carriers via contact layer 24 into the current distribution layer 11b.

As outlined in FIG. 1, the material of metal contact 20 is disposed in a recess of dielectric material of layer 22, and in contact with contact layer 24. The dielectric material further extends towards the top surface of the semiconductor layer 11 surrounding the contact layer 24, and covering the sidewalls of semiconductor layer 11, respectively. The dielectric material 25 further extends onto the sidewalls of the active layer and partially onto the semiconductor layer 13.

The structure is similar to conventional optoelectronic devices, in which mesa etched sidewalls of the semiconductor layer stack are covered by a respective dielectric material to prevent the generation of dangling bonds resulting in non-radiative recombination centres. In addition, the dielectric material of layers 22, 23 and 25 surrounding contact layer 24 and the semiconductor layer 11 as well as the active layer 12 prevents diffusion of oxygen or damage thereof.

In the present embodiment, the main emission surface 14 of the optoelectronic device 1 corresponds to the top surface of semiconductor layer 13. The main emission surface is free from any contact material, but a structured contact layer 30 is deposited on the top surface of layer 13.

More particularly, the structured contact layer 30 comprises a ring shaped structure, but does not extend across a portion of the semiconductor layer 13, which is projected to reside above contact layer 24 or active layer 12. In other words, the material of contact layer 30 is removed to expose the main emission surface 14 and only resides on a portion of the semiconductor layer 13 that is not directly arranged above the active layer 12 or contact layer 24. As a result thereof, contact layer 24 as well as the structured contact layer 30 are spatially offset towards each other in a lateral direction with portion 40 adjacent to both of them.

Said portion of 40 is formed by a projection towards the active layer 12 of the outer edges of the respective contact layer 24 and 30 facing each other. It defines a common portion of active layer 12, which is closest to the respective contact layers 24 and 30, respectively. In operation of the optoelectronic device, charge carriers provided by structured contact layer 30 will most likely injected into the active layer within portion 40 and subsequently recombine with charge carrier of opposite conductivity provided by contact layer 24. In other words, the carrier injection into the active layer 12 is constraint within portion 40 of the optoelectronic device and therefore not equally distributed across the overall active layer 12. The section of active layer 12 within portion 40 is referred to as active region, as most light emission will take place in said section during operation.

While the charge carrier constraint to portion 40 of active layer 12 may result in a reduced light emission, the removal of the contact layer 30 on the main emission surface 14 may reduce potential absorption by contact layer 30 and therefore improve the overall light emission through surface 14. By roughening or etching the surface 14, the light extraction can be further improved.

A top view of the respective embodiment of FIG. 1 is presented in FIG. 2. As indicated, the structured contact layer 30 forms a ring shaped structure surrounding the portion 40 implemented by a projection of structured contact layer 30 and contact layer 24 towards the active layer 12, respectively. In operation of the device, it is likely that the main emission results from active region in portion 40 due to the charge carrier constraints. By structuring the respective contact layer 30, the layer stack 12 or contact layer 24, one can change the shape and size of portion 40, thereby controlling the light emission during the modulation of the current into the optoelectronic device.

FIG. 3 illustrates a further embodiment in accordance with the proposed principle. Same elements comprise the same reference numerals. In the embodiment, the dielectric material of insulating layers 22, 23 and 24 is extended across the side surfaces of the optoelectronic device and therefore covers not only the sidewalls of semiconductor layer 11 and active region 12, but also the side wall of semiconductor layer 13. As illustrated, the dielectric layer material 26 extends from the bottom surface of contact layer 24 implementing recess 21 across the sidewalls all the way up to the level of the main emission surface 14. In addition, material of metal contact 20 is deposited on the dielectric material 26, acting as a mirror for light being emitted sideways.

In some aspects, the second semiconductor layer 13 comprises a highly doped current distribution layer 13c adjacent to contact layer 30. The highly doped current distribution layer 13c distributes the charge carriers being injected from contact layer 30 substantially equal across the semiconductor area for uniformly injecting the charge carrier into the active layer. The inventors now propose to remove a section or part of the highly doped current distribution layer 13c to restrain the carrier injection to a smaller portion.

FIG. 4 illustrates a respective embodiment. In this solution, a central portion of the current distribution layer 13c is removed, exposing the main emission surface 14 being the top surface of sublayer 13b of second semiconductor layer 13. The area of the current distribution layer 13c being removed is slightly smaller than the respective area of contact layer 24. As a result, contact layer 24 overlaps in edge portions with the respective edge portion of structured contact layer 30. Hence, an overlapping portion 41 is implemented, in which the carrier injection through contact layer 24 and structured contact layer 30 takes place. The charge carriers are transported into the active region within the overlapping portion 41 or closely adjacent to it. Hence, a partial removal of the current distribution layer can further constrain the current injection into the active layer significantly, thereby increasing the current density in the active region of overlapping portion 41.

The exposed surface of transportation sublayer 13b can be protected by depositing an insulating layer material in the recess. This insulating layer material (not shown in FIG. 4) covers the main emission surface 14 as well as the sidewalls surfaces of the exposed remaining parts of current distribution layer 13c. In some further instances, the recess in semiconductor layer 13 can be further extended towards the active layer and even cut through the active layer 12 in order to further constrain the charge carriers to the overlapping portions 41.

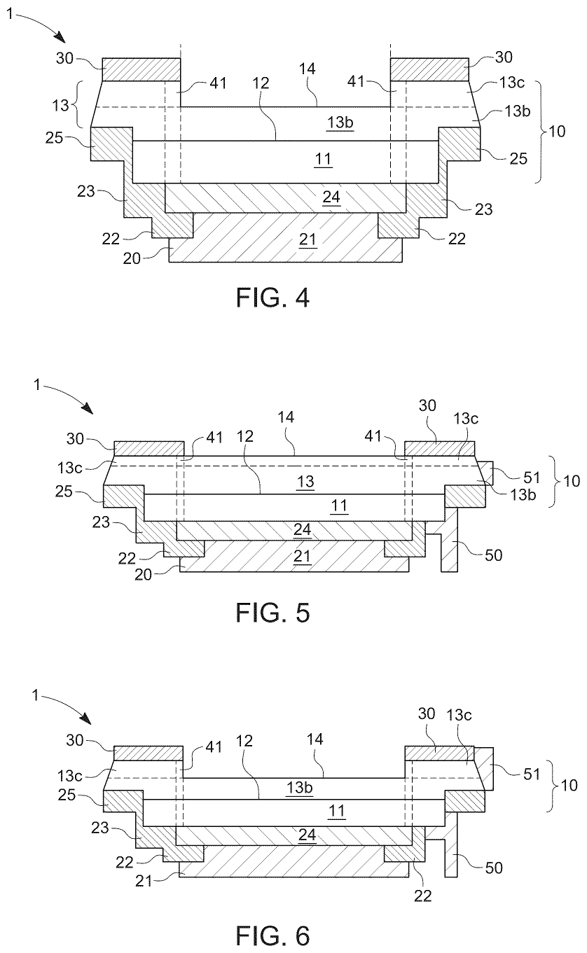

A further aspect, illustrated in FIG. 5 relates to an improvement of charge carrier removal during a modulation of the current through the optoelectronic device.

For this purpose, an additional secondary electrode is placed to the p-doped or n-doped side, respectively to further flush the active region with charge carriers or deplete it during modulation. Hence, rise and fall times will become faster (or steeper) and the optoelectronic device is switched significantly faster than conventional devices. This is achieved by providing or depleting the active region of charge carriers for generating the emission light.

FIG. 5 illustrates two secondary electrodes 50 and 51, respectively. Electrode 50 is arranged on an exposed portion of the first semiconductor layer 11 close to the active region 12. For this purpose, a portion of the dielectric material 23 is removed and replaced by a contact material of secondary electrodes 50. Likewise, a second secondary contact electrode 51 is arranged on an exposed sidewall portion of current distribution layer 13c and current transport layer 13b, respectively. Electrode 51 is separated from structured contact layer 30 to be able to independently control secondary electrode 51.

The secondary electrodes 50 and 51 in the present example are located on a specific side of the optoelectronic device. However, the secondary electrodes can be extended and implemented as ring electrodes surrounding the sidewall portions of the first semiconductor layer 11 and the second semiconductor layer 13, respectively. In such embodiment, additional carrier injection is conducted uniformly around the active layer 12 for increasing the charge carrier injection and depletion. In the embodiment of FIG. 5, the overlapping portions 41 are formed by the respective edge portions of contact layer 24 and 30 projected onto the active region (section of active layer 12 commonly in between the overlapping portions).

FIG. 6 illustrates a device that combines features of the embodiment of FIG. 4 with the embodiment of FIG. 5 and the additional secondary contact electrodes 50 and 51, respectively. In the embodiment of FIG. 6, a central portion of the current distribution layer 13c is removed, forming a central recess and exposing the top surface of current transport layer 13b. The secondary electrodes 50 contacts the first semiconductor layer 11 independently from the main contact layer 24. In contrast thereto, secondary electrode 51 contacts second semiconductor layer 13, but is also shortcut with the structured contact layer 30. Consequently, the overall surface area of the structured contact layer 30 is increased in the embodiment of FIG. 6 by the second secondary electrode 51. The first secondary electrode 50 can be activated or deactivated independently depending on the switching and modulation speeds desired.

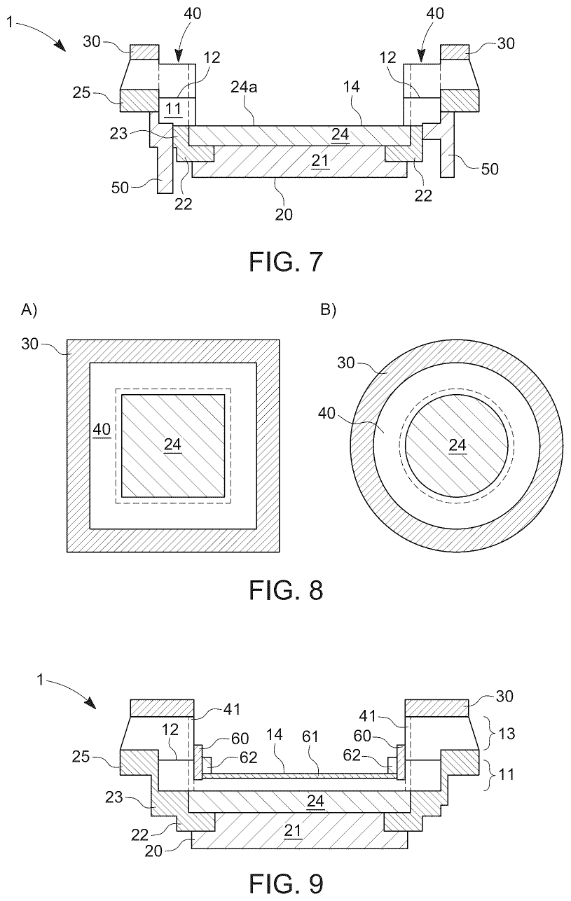

FIG. 7 illustrates a further embodiment, in which the secondary electrode 50 is arranged surrounding a portion of first semiconductor layer 11, but isolated by material 22 and 23 from the contact layer 24 and the metallic contact 20, respectively. Furthermore, in the present embodiment the recesses further extends down to contact layer 24, thereby removing also the central portion of active layer 12 as well as the material of the first semiconductor layer 11. As a result, a ring-shaped structure with the current constraint portions 40 and the active region remains as an optoelectronic device. The structured contact layer 30 is spatially offset in lateral direction to contact layer 24 by the non-overlapping portion 40. Any current injection from contact layer 24 or structured contact layer 30 will most likely recombine within the current constraint portion 40. In addition, the secondary electrode 50 is in electrical contact with portion 40 and particularly with the first semiconductor layer 11 defining the current constraint portion 40. The close proximity of the secondary contact electrodes 50 may improve the overall switching speed and rise and fall time.

The structured contact layer 30 as well as the resulting recess can have various forms and shapes as indicated in a top view illustrated in FIGS. 8A and 8B. FIG. 8A illustrates a top view of an optoelectronic device, in which the structured contact layer 30 comprises a substantially rectangular shape, whereas the respective current constraint portion 40 with its active region is also of a rectangular shape. Any light emission out of the optoelectronic device during operation of the device is now given out of the surface of portion 40 either from its top surface or side surface thereof.

FIG. 8B illustrates a similar embodiment, in which the structured contact layer 30 is shaped as a circle. Likewise portion 40 with its active region of semiconductor material as well as the recess exposing the contact layer 24 is also shaped surface.

In some embodiments, the recess is filled with a dielectric transparent material to provide an improved emission out of the optoelectronic device and protect the surface of portion 40 from oxidizing or any mechanical damage. In this regard, the top surface as well as the side surface of portion 40 or portion 41 can be further structured to provide an improved outcoupling. In addition, the centrally arranged recess can be filled with a converter material, for example quantum dots and the like. To enable light conversion of the optoelectronic device, however, the lifetime for photons being absorbed and converted by the converting material should be significantly smaller than the switching or modulation period of the optoelectronic device with the current constrain in accordance with the proposed principle to avoid switching speed reduction or other disadvantages.

The previous embodiments of FIGS. 5, 6 and 7 illustrate secondary electrodes to injected additional charge carriers into the semiconductor material in order to increase or deplete the charge carrier density in the active region (that is the section of active layer in portion 40 of 41, respectively).

However, the present embodiments can be amended to provide a transistor like structure of optoelectronic devices, in which one or more gates 60, 61 are arranged on the exposed sidewalls of the active layer 12. Those gates act like a MOSFET gate, whereas a potential applied to the respective dielectric gate changes the channel and the active layer band structure and therefore increases or decreases the internal resistance or current flow. Such approach applied to optoelectronic devices in accordance with the proposed principle improves the switching speed.

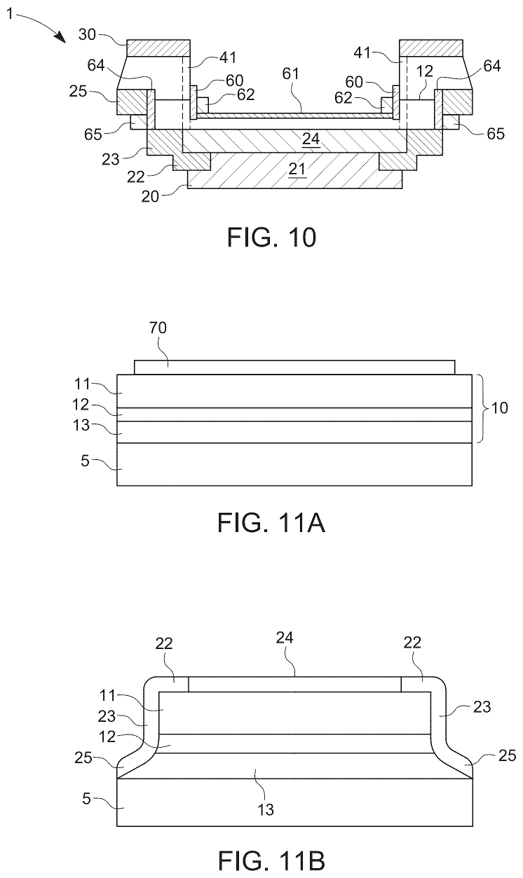

FIGS. 9 and 10 illustrate a respective exemplary embodiment of such gated optoelectronic device.

In FIG. 9 the optoelectronic device comprises a recess similar to the embodiment of FIG. 6 or 7, whereas the semiconductor layer 13 as well as a portion of layer 11 is removed, exposing the sidewalls of second semiconductor layers 13, the active layer 12 and a portion of sidewalls of layer 11. The exposed top surface of first semiconductor layer 11 is covered by a small layer 61 of dielectric material. A gate 60, also of a dielectric material, is deposited on the sidewalls of the active region and extends slightly below and above the active region, thereby also covering portions of the sidewalls of layer 13 and 11. In other words, the gate 60 covers the multi-quantum well structure of the active region and the adjacent cladding layers of the first and second semiconductor layer, for example.

On top of the gate 60, a metal contact 62 is applied. When seen from the top, gate 60 and metal contact 62 are implemented as a ring-shaped circumferential structure within the recess of the device. By providing a voltage to the metal contacts 62, the band structure adjacent to gate 60 is changed and distorted depending on the thickness of overlapping portion 41 and the size of the current constraint portion. Hence gate 60 can act as a switch or as a modulator changing the overall current into the active region.

FIG. 10 illustrates a further embodiment, in which the respective gates are implemented on both sidewalls of the active layer 12 at the respective current constraint portions 41. In particular, the first gate structure is implemented on the inner sidewalls of active layer 12, that is facing the central region of the optoelectronic device, while a second gate 64 shaped as ring surrounding the active layer 12 completely on the outside.

A metal contact 65 is arranged on the second gate 64. The metal contact may be distributed across gate 64, or slightly displaced as indicated in FIG. 10. In both cases (for gates 60 and 64) by applying a voltage charge carriers can repel or attracted resulting in injection or depletion within the active region.

Both gates are controlled independent from each other to apply respective voltages to the active layer 12 and the current constraint portion 41, respectively. By varying the voltage to the respective gates, the overall emission is modulated depending on the switching speed and modulation frequency of the gate potential. As a result, the device can be operated in a continuous manner, whereas the modulation, in particular an amplitude modulation is performed by applying a potential to the gate voltage.

In the embodiments of FIGS. 9 and 10, the gate material is applied across the active region. However this may not be necessary. Rather the gate material can also be applied only on one or both doped layers close to the active region, but leave the active region free of gate material. Leaving the surface of active region free of any gate material and thus free of an electric potential, may be beneficial for the IQU within the active region. However, any transport channel in the doped layers can be constricted with an electric potential provided by the gate structure and the metal on the other side of the gate.

In a similar operation, the secondary electrodes 50 in FIGS. 6 and 7 can be used to inject or deplete charge carriers into the active region of portions 40 and 41, respectively. These embodiments enable to modulate the emission of the optoelectronic device by an additional current or voltage signal, whereas the optoelectronic device itself is already operated above its threshold.

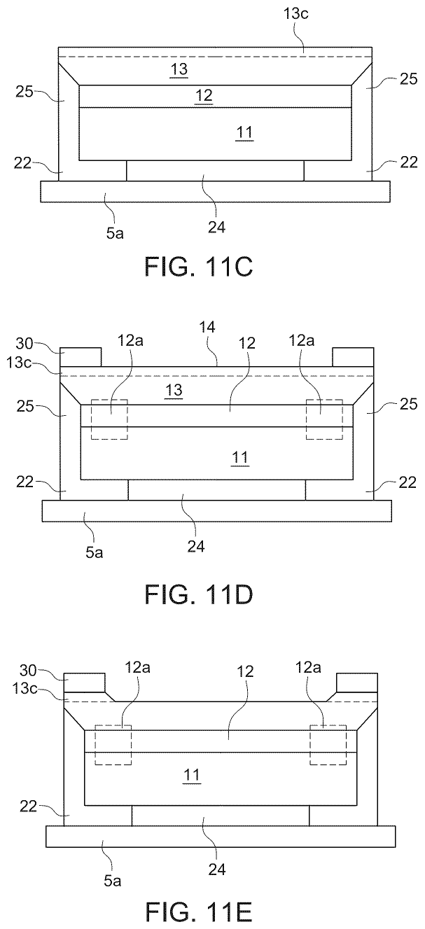

FIGS. 11A to 11E illustrate various steps for processing an optoelectronic device in accordance with the proposed principle.

The method includes among other steps the processing of a semiconductor layer stack 10 based on a III-V semiconductor material on a temporary growth substrate 5. The layer stack 10 is deposited as a plurality of individual layers ad sublayers thereof on a growth substrate 5, which is suitably prepared for the subsequent growth processes. For example, the growth substrate 5 contains one or more buffer layers to reduce surface defects and obtain a planar and defect free growth surface.

A second semiconductor layer 13 is deposited on buffer layers of substrate 5. As previously mentioned, the second semiconductor layer 13 may comprise a plurality of sublayers including but not limited to a first highly doped sublayer 13c (not shown in FIG. 11A) adjacent to the buffer layer of the growth substrate 5. The highly doped sublayer represents the current injection layer as in conventional devices. Further sublayers may include a doped charge carrier transport layer as well as cladding layer. The cladding layer is undoped and separates a multi-quantum well structure 12 from the doped transport sublayer of second semiconductor layer 13.

Active layer 12 is implemented with a multi-quantum well structure comprising a plurality of alternating barrier and quantum well layers, respectively. A bandgap in the barrier layer is slightly increased in comparison to an adjacent quantum well layer. Further measures like silicon doping in the barrier layers and other aspects can be implemented when the depositing active layer 12.

The top surface of active layer 12 is covered by another undoped cladding layer being part of first semiconductor layer 11 deposited thereupon. On top of the undoped cladding layer, a charge carrier transport sublayer as well as a current distribution sublayer of semiconductor layer 12 is deposited. First and second semiconductor layers 11 and 13 therefore comprise a plurality of differently doped sublayers enabling certain functionalities. The doping distribution as well as the doping concentration can already reflect some of the subsequent steps and measures taken to improve the switchability of the optoelectronic device in accordance with the proposed principle.

On the top surface of layer 11, a hard mask layer is deposited and subsequently structured to cover a central portion of the layer stack 10.

The first semiconductor layer 11, the active layer 12 and portions of second semiconductor layer 13 are etched in a subsequent mesa etching process step illustrated in FIG. 11B. the mesa etching process utilizes the hard mask 70 to provide the mesa etched structure of an optoelectronic device. The mesa etch is extended along the first semiconductor layer 11, the multi-quantum well structure 12 and partially onto the second semiconductor layer 13. The respective exposed sidewalls are then cleaned and covered with a thin layer of a dielectric material like for example Al2O3.

In a subsequent step, further transparent dielectric material is deposited on the top surface as well as the sidewalls forming the dielectric material, portions 22 on the top surface, 23 on the side wall of semiconductor layer 11 and 12 as well as 25 on the sidewall of the semiconductor layer 13. Hard mask 70 may then be removed. This step can be also done prior to applying the dielectric material.

In such case, the dielectric material being deposited thereupon is subsequently structured to form a recess, which is filled highly doped contact layer material forming contact 24. In the present embodiment, contact layer 24 comprises a diameter smaller than the diameter of active layer 12, with some dielectric material being on top of layer 11. Still variants to this part of the structure are easily derivable with the shape of contact layer 24 already providing some current injection constraints.

The highly doped material of contact layer 24 can either be a semiconductor material but may also consists of a metal or an alloy or a combination thereof.

In a subsequent step, the layer stack is re-bonded with the surface of the contact layer 24 and dielectric material 22 being attached to a temporary support carrier 5a. The growth substrate 5 is removed to expose the surface of second semiconductor layer 13 and particularly the highly doped current injection sublayer 13c thereof. The resulting component is illustrated in FIG. 11C.

In a subsequent step shown in FIG. 11D, material of a contact layer 30 is deposited on the top surface and structured such as to form a central recess and exposing top surface 14 of second semiconductor layer 13. The top surface may also form a part of the main emission surface of the optoelectronic device later on. The material of contact layer 30 comprises a highly doped semiconductor material but may also include a metal. Contact layer 30 is configured with a very low resistance on the interface between contact layer 30 and highly doped current injection sublayer 13c.

As indicated in FIG. 11D, the recess within the material of contact layer 30 is adjusted such that the inner edges of contact layer 30 facing each other are located outside a projection of contact layer 24 on the other side when seen from a top view. Likewise, the outer edge of contact layer 24 when seen from top to not intersect with material of contact layer 30.

As a result a circumferential portion of active layer 12 is formed, which is outside the projection of contact layer 24 onto the active layer 12 as well as outside the projection of the structured contact layer 30 on the active layer 12. This area marked as 12a in FIGS. 11D and 11E is referred to as active region.

The constraint with respect to a current injection is further enhanced by removing a portion of the second semiconductor layer 13 and particularly sublayer 13c in the central recess. This is achieved by using for example the contact layer 30 as a mask layer and selectively etching a portion of sublayer 13c within the central recess of the structured mask layer 30. This recess improves the current constraints such that a current injected via contact layer 30 and contact 24 will diffuse mainly into the section 12a of active layer 12 forming the active region of the optoelectronic device.

1.-19. (canceled)

20. An optoelectronic device comprising:
a semiconductor layer stack comprising a planar first semiconductor layer of a first doping type, an active layer and a second semiconductor layer of a second doping type, wherein the second semiconductor layer comprises a main emission surface layer portion;
a contact layer arranged on the first semiconductor layer opposite at least a first portion of the active layer; and
a structured contact layer arranged on the second semiconductor layer opposite a second portion of the active layer,
wherein the first portion and the second portion are spatially offset in a lateral direction to each other and configured to increase a local charge carrier density in an active region of the active layer partially common to or adjacent to the first and second portions of the active layer, and
wherein the active region is defined by a projection of an overlapping section of the first and second portions onto the active layer.

21. The optoelectronic device according to claim 20,
wherein the active region is defined by a projection of edges of the contact layer and the structured contact layer facing each other onto the active layer, and/or
wherein the active region is formed by a closed structure surrounding one of the first portion or the second portion and being surrounded by a respective other one of the first portion or the second portion, and/or
wherein the active layer comprises a larger area than an area of the contact layer.

22. The optoelectronic device according to claim 20, wherein the structured contact layer forms a closed structure surrounding the main emission surface layer portion.

23. The optoelectronic device according to claim 20,
wherein the second semiconductor layer is at least partially recessed in an area of the main emission surface layer portion, and/or
wherein the second semiconductor layer comprises a highly doped current spreading sublayer that is arranged partially opposite the second portion of the active layer, and wherein optionally a thickness of the current spreading sublayer opposite at least a first portion of the active layer is reduced, and/or
wherein the active layer forms a closed structure with a central portion comprising a material different from a material of the active layer.

24. The optoelectronic device according to claim 20, further comprising a dielectric material covering sidewalls of the contact layer, the first semiconductor layer and the active region, and optionally wherein a metal of a metal contact contacting the contact layer is located on portions of the dielectric material.

25. The optoelectronic device according to claim 20, further comprising a first secondary electrode electrically conducting one of the first semiconductor layer or the second semiconductor layer at a location outside a respective one of the first portion or the second portion.

26. The optoelectronic device according to claim 25, further comprising a second secondary electrode electrically conducting the other one of the first semiconductor layer or the second semiconductor layer at a location outside the respective first portion or the respective second portion, and/or wherein the first and/or the second secondary electrode form a ring-shaped structure surrounding the one of the first portion or the second portion.

27. The optoelectronic device according to claim 20, further comprising:
a dielectric gate material deposited on a sidewall portion of the active layer extending partially on an adjacent sidewall portion of at least one of the first and second semiconductor layer; and
a metal contact forming a conductive contact gate on the dielectric gate material.

28. The optoelectronic device according to claim 27,
wherein the dielectric gate material is arranged on a circumferential inner sidewall of the active region, and/or
wherein the dielectric gate material is arranged on a circumferential outer sidewall of the active layer.

29. The optoelectronic device according to claim 27,
wherein the dielectric gate material is arranged parallel to a diffusion direction of the charge carrier in operation of the device, and/or
wherein the dielectric gate material is arranged substantially perpendicular to the active region.

30. A method for processing an optoelectronic device, the method comprising:
providing a mesa-etched layer stack having a first semiconductor layer of a first doping type, a second semiconductor layer of a second doping type and an active layer in between;
depositing a contact layer on the first semiconductor layer opposite at least a first portion of the active layer;
rebonding the layer stack and removing a substrate to expose the second semiconductor layer; and
depositing a structured contact layer on the second semiconductor layer opposite a second portion of the active layer such that at least a portion of a surface of the second semiconductor layer opposite the contact layer is exposed,
wherein depositing the contact layer and the structured contact layer are conducted such that the layers are laterally spatially offset from each other to increase a local charge carrier density in an active region of the active layer partially common to or adjacent to the first and second portion of the active layer,
wherein the active region is defined by a projection of an overlapping section of the first and second portions onto the active layer.

31. The method according to claim 30,
wherein the active layer comprises a larger area than an area of the contact layer, and/or
wherein the active region is defined by a projection of edges of the contact layer and the structured contact layer facing each other onto the active layer, and/or
wherein the active region is formed by a closed structure surrounding one of the first portion or the second portion and being surrounded by a respective other one of the first portion or the second portion.

32. The method according to claim 30, further comprising:
recessing the surface of the second semiconductor layer opposite the contact layer thereby forming a recess and removing at least one of:
a portion of a highly doped current distribution layer being part of the second semiconductor layer,
a portion of the active layer, or
a portion of the first semiconductor layer opposite the contact layer.

33. The method according to claim 30, wherein providing the mesa-etched layer comprises:
depositing a dielectric material on sidewalls of the first semiconductor layer and the active layer, and optionally on portions of the second semiconductor layer; and
optionally depositing a metal contact material on the dielectric material.

34. The method according to claim 30, further comprising:
depositing a first secondary electrode electrically conducting one of the first semiconductor layer and the second semiconductor layer at a location outside a respective one of the first portion or the second portion; and
optionally depositing the first secondary electrode as a ring-shape structure surrounding the respective one of the first portion or the second portion.

35. The method according to claim 34, further comprising:
depositing a second secondary electrode electrically conducting the other one of the first semiconductor layer or the second semiconductor layer at a location outside a respective first portion or a respective second portion; and
optionally depositing the second secondary electrode as a ring-shaped structure surrounding the respective one of the first portion or the second portion.

36. The method according to claim 30, further comprising:
depositing a dielectric gate material on a sidewall portion of the active layer extending partially on an adjacent sidewall portion of at least one of the first semiconductor layer or the second semiconductor layer; and
depositing a metal contact forming a conductive contact gate on the dielectric gate material.

37. The method according to claim 36,
wherein the dielectric gate material is arranged on a circumferential inner sidewall of the active region, and/or
wherein the dielectric gate material is arranged on a circumferential outer sidewall of the active layer.

38. The method according to claim 36,
wherein the dielectric gate material is arranged parallel to a diffusion direction of the charge carrier in operation of the device, and/or
wherein the dielectric gate material is arranged perpendicular to the active region.
